(19) United States
(12) Patent Application Publication
(10) Pub. No.: US 2025/0040455 A1
(43) Pub. Date: Jan. 30, 2025

(54) METHOD OF MANUFACTURING AN ELECTRONIC COMPONENT

(71) Applicant: Commissariat á I'Énergie Atomique et aux Énergies Alternatives, Paris (FR)

(72) Inventors: Christelle Boixaderas, Grenoble (FR); Nicolas Posseme, Grenoble (FR); Benjamin Fontaine, Crolles (FR); Jerome Dubois, Crolles (FR); Pascal Gouraud, Crolles (FR)

(73) Assignee: Commissariat á I'Énergie Atomique et aux Énergies Alternatives, Paris (FR)

(21) Appl. No.: 18/780,788

(22) Filed: Jul. 23, 2024

(30) Foreign Application Priority Data
Jul. 24, 2023 (FR) 2307957

(51) Int. Cl. H10N 70/00; H10B 63/10

(52) U.S. Cl. CPC H10N 70/063; H10B 63/10; H10N 70/8828

(57) ABSTRACT

A method of manufacturing an electronic component including a step a) of etching at least a first layer made of a material containing germanium and including one element amongst oxygen, sulfur, selenium and tellurium followed, without bringing back into contact with oxygen, by a step b) of treating the etched flanks of the first layer with a hydrogen plasma.

### CROSS-REFERENCE TO RELATED APPLICATION

This application claims priority to French application number 2307957, filed Jul. 24, 2023. The contents of this application is incorporated herein by reference in its entirety.

### TECHNICAL FIELD

The present description relates generally to the methods of manufacturing electronic components and more particularly to the methods of manufacturing non-volatile Phase Change Memory cells (PCM) or cells with an Ovonic Threshold Switching (OTS).

### BACKGROUND ART

Phase change memories or PCM are non-volatile memories based on the properties of phase change materials. A phase change material is a material having the ability to change state under the effect of heat and more particularly to switch between a crystalline state and an amorphous state which is more highly resistive than the crystalline state. In order to store data, phase change memories take advantage of the fact that the electrical resistances of the amorphous phase of phase change materials and electrical resistances of the crystalline phase are different.

The OTS cells rely on the ability of the material of which same is composed to change state depending on the magnitude of the voltage applied across the cell.

There is a need to improve the methods of manufacturing memory cells and switching cells.

### SUMMARY OF INVENTION

One embodiment provides a method of manufacturing an electronic component comprising a step a) of etching at least a first layer made of a material containing germanium and comprising one element amongst oxygen, sulfur, selenium and tellurium followed, without bringing back into contact with oxygen, by a step b) of treating the etched flanks of the first layer with a hydrogen plasma.

According to one embodiment, the first layer is a chalcogenide material.

According to one embodiment, the first layer is located in a stack including a conductive layer and a resistive element surrounded by an insulating layer, the first layer being in contact through a first face with the conductive layer and, through a second face, opposite the first face, with the resistive element.

According to one embodiment, the first layer is made of a phase change material.

According to one embodiment, the stack includes a second layer made of an ovonic threshold switching material and another conductive layer, the second conductive layer being in contact through a first face with the conductive layer and, through a second face, opposite the first face, with the other conductive layer.

According to one embodiment, the first layer is made of a threshold switching material.

According to one embodiment, the step of etching the first layer corresponds to an etching using halogen-plasma.

According to one embodiment, the first layer contains tellurium.

According to one embodiment, the first layer consists of an alloy of germanium, tellurium and antimony.

According to one embodiment, the first layer contains selenium, for example contains antimony, selenium and germanium.

According to one embodiment, the DC or pulsed bias voltage is less than 100 V, for example less than 10 V in absolute value, for example less than 1 V in absolute value, for example zero.

According to one embodiment, the plasma includes molecular hydrogen or ammonia, the flow of each gas of the plasma being comprised between 25 cm³/min and 500 cm³/min.

According to one embodiment, the power of the plasma source is comprised between 200 W and 1000 W and the pressure applied in the reactor is comprised between 0.4 Pa and 13.3 Pa.

According to one embodiment, the etching step is a step of etching using halogen-plasma.

According to one embodiment, during step a), the etching is carried out through an etching mask deposited on the first layer beforehand, the treatment of the flanks applied during step b) leading to the removal of said etching mask.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1A, FIG. 1B, FIG. 1C and FIG. 1D illustrate partial and schematic sectional views of successive steps of an example of embodiment of a method of manufacturing an electronic component; and

FIG. 2A, FIG. 2B, FIG. 2C, FIG. 2D and FIG. 2E illustrate partial and schematic sectional views of successive steps of a method of manufacturing an electronic component according to one embodiment.

### DESCRIPTION OF EMBODIMENTS

Like features have been designated by like references in the various Figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. More particularly, the method of manufacturing a single memory cell has been illustrated, the embodiments described are however applicable to the simultaneous manufacture of multiple cells organized in an array on the same plate. Furthermore, electrical connections between the cells and selection circuits composing the memory circuit have not been discussed in detail, the embodiments described being compatible with the usual selection circuits as well as the corresponding addressing circuits thereof.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferentially within 5%.

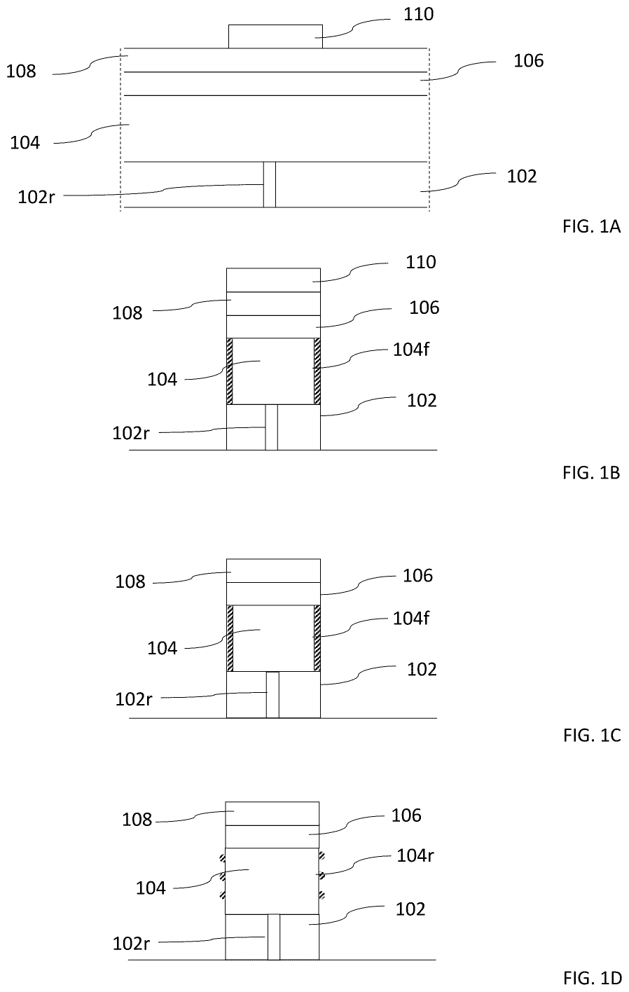

FIG. 1A, FIG. 1B, FIG. 1C and FIG. 1D illustrate partial and schematic sectional views of successive steps of an embodiment of a method of manufacturing a phase change memory cell.

FIG. 1A illustrates an initial structure including an insulating layer 102 and a resistive heating element 102r, also called a “heater”, extending vertically through the insulating layer 102. As an example, the resistive element 102r is surrounded laterally by the insulating layer 102. The insulating layer 102 can be used for example for insulating and laterally separating the resistive element 102r from another neighboring resistive element 102r (not visible in the figures). As an example, the resistive element 102r is flush, via the upper face thereof, with the upper face of the insulating layer 102 and, via the lower face thereof, with the lower face of the insulating layer 102.

The starting structure further includes a layer 104 of a material based on germanium and an element of the column sixteen of the periodic table.

As an example, the layer 104 is made of a chalcogenide material. As an example, the layer 104 is made of a phase change material called the PCM layer. As an example, the PCM layer 104 is made of a material containing germanium and tellurium. In a variant, the PCM layer 104 is made of a material containing germanium and selenium. For example, the PCM layer 104 contains an alloy of germanium, antimony and tellurium or GST.

In a variant, the layer 104 is made of an OTS material.

The PCM layer 104 is for example formed on the upper face of the insulating layer 102 and of the resistive element 102r. The PCM layer 104 is for example in contact, via the lower face thereof, with the upper face of the insulating layer 102 and of the resistive element 102r. As an example, the PCM layer 104 extends over the entire surface of the upper face of the insulating layer 102.

The starting structure further includes a conductive layer 106. The conductive layer 106 is for example formed on the upper face of the PCM layer 104. The conductive layer 106 is for example in contact, via the lower face thereof, with the upper face of the PCM layer 104. As an example, the conductive layer 106 extends over the entire surface of the upper face of the PCM layer 104. As an example, the conductive layer 106 corresponds to the upper electrode of the memory cell formed during the following steps.

Furthermore, the starting structure comprises an insulating layer 108. The insulating layer 108 is for example formed on the upper face of the conductive layer 106. The insulating layer 108 is for example in contact, via the lower face thereof, with the upper face of the conductive layer 106. As an example, the insulating layer 108 extends over the entire surface of the upper face of the conductive layer 106.

The insulating layer 108 is for example covered by an etching mask 110. The etching mask 110 is for example formed over and in contact with the upper face of the insulating layer 108. For example, the etching mask 110 does not extend over the entire surface of the upper face of the layer 108. The etching mask 110 is for example formed opposite the desired location for the memory cell.

Although not visible in the figures, the stack formed by the layers 102, 104, 106, 108, 110 rests e.g, on and in contact with the upper face of an integrated control circuit, comprising one or a plurality of devices for selecting phase change memory cells. As an example, the selection elements are transistors, diodes or OTS elements.

FIG. 1B illustrates a structure obtained at the end of a step of etching the stack formed by the insulating layer 102, the PCM layer 104, the conductive layer 106 and the insulating layer 108.

During such step, the parts of the layers 102, 104, 106, 108 not protected by the etching mask 110 are removed. The etching of said layers comprises, inter alia, a step using halogen-plasma etching. As an example, the halogenated etching is carried out using hydrogen bromide (HBr), chlorine (Cl₂), tetrafluoromethane (CF₄), fluoromethane (CFₓ, wherein x is comprised between 0.1 and 4).

As an example, during such step, the PCM layer 104 has the flanks 104f modified to a greater extent than the layers 102, 106 and 108.

During such step, the flanks 104f of the PCM layer 104 are enriched in halogen atoms at the flanks 104f thereof. As an example, the PCM layer 104 is enriched over a thickness comprised between 1 nm to 20 nm, for example comprised between 1 nm to 10 nm. As an example, the flanks 104f of the PCM layer 104 include, at the end of said step, a percentage of halogen, for example in the first twenty nanometers, comprised between 1% and 30%.

As an example, whenever the PCM layer 104 is made of a chalcogenide material containing tellurium, during such step, the flanks 104f of the PCM layer 104 are also enriched with tellurium.

FIG. 1C illustrates a structure obtained at the end of the step of removing the etching mask 110.

The mask 110 is removed for example by an etching step using oxygen plasma, called stripping.

As an example, the steps illustrated in FIGS. 1B and 1C are carried out under a pressure, for example lower than 100 Pa, for example lower than 1 Pa. As an example, the steps of FIGS. 1B and 1C are carried out within the same equipment. As an example, at the end of the step illustrated in FIG. 1B, the structure is not brought back into contact with oxygen before the step illustrated in FIG. 1C.

FIG. 1D illustrates a structure obtained at the end of a step of cleaning the structure illustrated in FIG. 1C.

The cleaning step illustrated in FIG. 1D is carried out for example by a wet chemical treatment. As an example, the cleaning is carried out using hydrofluoric acid and glycolic acid.

Such cleaning step is carried out for example while the structure has been put back into the air, i.e. when same is carried out under atmospheric pressure and when the structure is no longer under vacuum or under an inert atmosphere. During venting and during such step, the halogen atoms present in the flanks 104f of the layer 104 are then degassed, i.e. same emerge from the structure. As an example, by degassing, the halogen atoms react with air and form residues 104r at the surface of the flanks 104f. As an example, the residues 104r can have dimensions going to 300 nm, for example to 200 nm. As an example, during such step, germanium oxide resulting from the reaction between the germanium present in the PCM layer 104, the surface of which has been altered during the cleaning step illustrated in FIG. 1C, and oxygen present in the air, is further formed on the flanks 104f of the PCM layer 104.

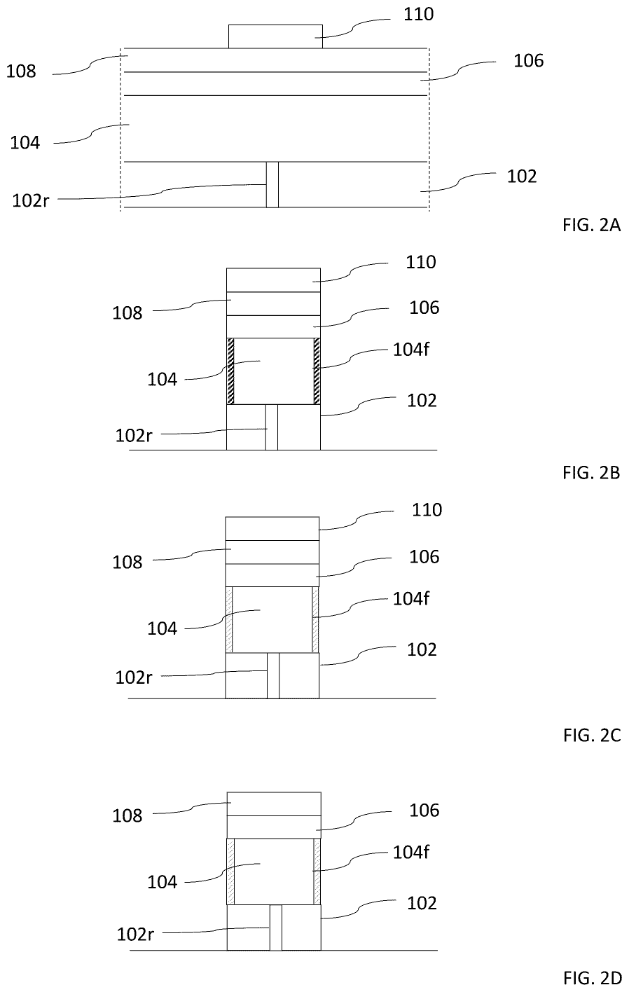

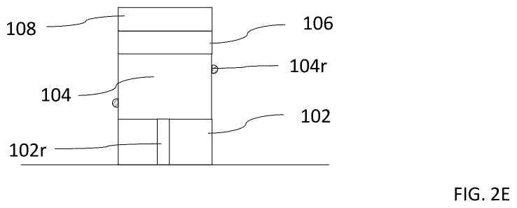

FIG. 2A, FIG. 2B, FIG. 2C, FIG. 2D and FIG. 2E illustrate partial and schematic sectional views of successive steps of a method of manufacturing an electronic component according to one embodiment.

FIG. 2A more particularly illustrates a starting structure identical to the starting structure illustrated in FIG. 1A.

The thickness of the PCM layer 104 is comprised for example between 30 nm and 100 nm, for example between 40 nm and 60 nm.

The conductive layer 106 is for example made of metal, for example a titanium alloy. The thickness of the conductive layer 106 is comprised for example between 5 nm and 40 nm, for example between 15 nm and 30 nm.

The insulating layer 108 is made for example of silicon nitride. The thickness of the insulating layer 108 is comprised for example between 5 nm and 40 nm, for example between 15 nm and 30 nm.

The mask 110 is made for example of carbon. The mask 110 has a thickness comprised for example between 200 nm and 400 nm, for example between 250 nm and 300 nm.

FIG. 2B illustrates a structure obtained at the end of a step of etching the stack formed by the insulating layer 102, the PCM layer 104, the conductive layer 106 and the insulating layer 108. Such step is identical to the step illustrated in FIG. 1B. As an example, such step is carried out in a capacitively coupled plasma (CCP) reactor or in an inductively coupled plasma (ICP) reactor.

FIG. 2C illustrates a structure obtained at the end of a step of treating the etched flanks 104f of the PCM layer 104. Such step is carried out at the end of the step illustrated in FIG. 2C without the structure being brought back into contact with oxygen.

As an example, the steps illustrated in FIGS. 2B and 2C are carried out within the same equipment.

Such step is carried out by a hydrogen plasma. As an example, the plasma is composed of molecular hydrogen or ammonia, for example with one neutral gas or with neutral gases such as argon or molecular nitrogen. In a plasma, neutral gases can help in the ignition and the stability of the plasma. In any case, the plasma used during such stage does not comprise oxygen.

During such step, the bonds formed at the flanks 104f between the halogen atoms and the elements of the PCM layer 104 are broken and the halogen atoms bonded to the flanks 104f of the PCM layer 104 are partially removed. Said atoms are for example replaced by hydrogen atoms which in turn bind to the flanks 104f of the layer 104. The above is referred to as restoring the surface state of the layer 104.

During such step, the DC or pulsed bias voltage applied to the plasma is relatively low, for example lower than 100 V in absolute value. As an example, during such step, the DC bias voltage is lower than 10 V in absolute value. As an example, during such step, the DC bias voltage is lower than 1 V in absolute value. Preferentially, during such step, the DC bias voltage is zero. Such low bias value makes it possible in particular not to consume too large a quantity of the flanks 104f of the PCM layer 104. As an example, under pulsed bias, the bias duty cycle, i.e. the percentage of time during which the bias voltage is applied to the substrate is comprised between 20% and 90% of the cycle time. As an example, under pulsed bias, the cycle frequency is comprised between 100 Hz and 5 kHz.

As an example, the flow of each gas of the plasma is comprised between 25 cm³/min and 500 cm³/min. As an example, the power of the plasma source is comprised between 200 W and 1000 W. As an example, the pressure applied in the reactor is comprised between 3 mTorr (i.e. about 0.4 Pa) and 100 mTorr (i.e. about 13.3 Pa). As an example, during such step, the temperature of the structure is comprised between 0° C. and 100° C. As an example, such step has a duration comprised between 5 seconds and 30 seconds, for example between 5 and 15 seconds.

During such step, in addition to the removal of the halogen atoms in the flanks 104f of the PCM layer 104, the plasma leads to a reduction in the tellurium percentage in the PCM layer 104, for example homogeneously throughout the PCM layer 104. As an example, such step also makes it possible to clean the flanks of the conductive layer 106 on which halogen atoms can form residues during venting after the etching step illustrated with reference to FIG. 2B.

FIG. 2D illustrates a structure obtained at the end of a step of removing the etching mask 110 from the structure illustrated in FIG. 2C, for example identical to the step of removing the etching mask 110 illustrated with reference to FIG. 1C. In a variant, the etching mask 110 is removed, by hydrogen plasma etching, during the step illustrated with reference to FIG. 2C.

FIG. 2E illustrates a structure obtained at the end of a step of cleaning the structure illustrated in FIG. 2D. Such step is for example similar to the step illustrated with reference to FIG. 1D, except that the flanks 104f of the layer 104 of the structure illustrated in FIG. 2D include fewer halogen atoms than the flanks 104f of the layer 104 of the structure illustrated in FIG. 1D.

During venting after the steps shown in FIGS. 2B, 2C and 2D and during said step, residues 104r are then formed on the surface of the flanks 104f of the PCM layer 104 but in a smaller proportion compared to the proportion of residues formed during the step illustrated in FIG. 1D.

An advantage of the present embodiment is that same can be used for preventing the appearance of residues on the flanks of the PCM layer, for controlling the composition of the flanks of the PCM layer and thereby for reducing surface roughness. In particular, in this way it is possible to improve the reliability and the lifetime of the memory cells.

Various embodiments and variants have been described. Those skilled in the art will understand that certain features of these embodiments can be combined and other variants will readily occur to those skilled in the art. In particular, although the step of treating the flanks of the PCM layer by hydrogen plasma is carried out between the halogen etching step and the step of removing the etching mask, provision can be made for the step to be carried out after or during the step of removing the etching mask and before the structure is vented.

In addition, a variant can be provided for, wherein each cell includes, above the conductive layer 106, a stack of a layer made of an OTS material and another conductive layer. In such variant, the OTS layer is in contact, via the lower face thereof, with the upper face of the conductive layer 106, and the other conductive layer is in contact with the OTS layer.

Finally, the practical implementation of the embodiments and variants described herein is within the capabilities of those skilled in the art based on the functional description provided hereinabove.

1. A method of manufacturing an electronic component comprising a step a) of etching at least a first layer made of a material containing germanium and comprising one element amongst oxygen, sulfur, selenium and tellurium followed, without bringing back into contact with oxygen, by a step b) of treating the etched flanks of the first layer with a hydrogen plasma.

2. The method according to claim 1, wherein the first layer is a chalcogenide material.

3. The method according to claim 1, wherein the first layer is located in a stack comprising a conductive layer and a resistive element surrounded by an insulating layer, the first layer being in contact through a first face with the conductive layer and, through a second face, opposite the first face, with the resistive element.

4. The method according to claim 1, wherein the first layer is made of a phase change material.

5. The method according to claim 3, wherein the stack includes a second layer made of an ovonic threshold switching material and another conductive layer, the second conductive layer being in contact through a first face with the conductive layer and, through a second face, opposite the first face, with the other conductive layer.

6. The method according to claim 1, wherein the first layer is made of a threshold switching material.

7. The method according to claim 1, wherein the step of etching the first layer corresponds to an etching using halogen-plasma.

8. The method according to claim 1, wherein the first layer contains tellurium.

9. The method according to claim 8, wherein the first layer consists of an alloy containing germanium, tellurium and antimony.

10. The method according to claim 1, wherein the first layer is a layer containing selenium, for example containing antimony, selenium and germanium.

11. The method according to claim 1, wherein the DC or pulsed bias voltage is lower than 100 V, for example lower than 10 V in absolute value, for example lower than 1 V in absolute value, for example zero.

12. The method according to claim 1, wherein the plasma includes molecular hydrogen or ammonia, the flow of each gas in the plasma being comprised between 25 cm³/min and 500 cm³/min.

13. The method according to claim 1, wherein the power of the plasma source is comprised between 200 W and 1000 W, and the pressure applied in the reactor is comprised between 0.4 Pa and 13.3 Pa.

14. The method according to claim 1, wherein the step of etching is a step of etching using halogen plasma.

15. The method according to claim 1, wherein, during step a), the etching is carried out through an etching mask deposited on the first layer beforehand, the flank treatment applied during step b) leading to the removal of said etching mask.
